(19) United States
(12) Patent Application Publication
(10) Pub. No.: US 2007/0193621 A1
(43) Pub. Date: Aug. 23, 2007

(54) PHOTOVOLTAIC CELLS

(75) Inventors: Christoph Brabec, Linz (AT); Jens Hauch, Haroldsberg (DE); Pavel Schilinsky, Nuremberg (DE)

Correspondence Address: FISH & RICHARDSON PC, P.O. BOX 1022, MINNEAPOLIS, MN, 55440-1022, US

(73) Assignee: KONARKA TECHNOLOGIES, INC., Lowell, MA (US)

(21) Appl. No.: 11/684,346

(22) Filed: Mar. 9, 2007

Related U.S. Application Data
(63) Continuation-in-part of application No. 11/643,271, filed on Dec. 21, 2006.
(60) Provisional application No. 60/752,608, filed on Dec. 21, 2005.
(60) Provisional application No. 60/780,560, filed on Mar. 9, 2006.
(60) Provisional application No. 60/888,704, filed on Feb. 7, 2007.

(51) Int. Cl. H02N 6/00; H01L 31/042

(52) U.S. Cl. 136/246; 977/734

(57) ABSTRACT

Photovoltaic cells containing a plurality of electrically conductive lines, as well as related systems, methods, modules, and components, are disclosed.

### CROSS REFERENCE TO RELATED APPLICATION

This application is a continuation-in-part of and claims priority under 35 U.S.C § 120 to U.S. Patent Application Serial Number 11/643,271, filed Dec. 21, 2006, which in turn claims priority under 35 U.S.C. § 119 to U.S. Provisional Patent Application Ser. No. 60/752,608, filed Dec. 21, 2005. This application also claims priority under 35 U.S.C. § 119 to U.S. Provisional Application Ser. No. 60/780,560, filed Mar. 9, 2006 and to U.S. Provisional Application Ser. No. 60/888,704, filed Feb. 7, 2007. The contents of the parent applications are hereby incorporated by reference.

### TECHNICAL FIELD

The invention relates to photovoltaic cells containing a plurality of electrically conductive lines, as well as related systems, methods, modules, and components.

### BACKGROUND

Photovoltaic cells are commonly used to transfer energy in the form of light into energy in the form of electricity. A typical photovoltaic cell includes a photoactive material disposed between two electrodes. Generally, light passes through one or both of the electrodes to interact with the photoactive material. As a result, the ability of one or both of the electrodes to transmit light (e.g., light at one or more wavelengths absorbed by a photoactive material) can limit the overall efficiency of a photovoltaic cell. In many photovoltaic cells, a film of semiconductive material (e.g., indium tin oxide) is used to form the electrode(s) through which light passes because. Although the semiconductive material can have a lower electrical conductivity than electrically conductive materials, the semiconductive material can transmit more light than many electrically conductive materials,

### SUMMARY

This invention relates to photovoltaic cells containing a plurality of electrically conductive lines, as well as related systems, methods, modules, and components.

In one aspect, this invention features an article that includes a first electrode containing a plurality of electrically conductive lines, a second electrode, and a photoactive layer between the first and second electrodes. The photoactive layer includes an electron donor material and an electron acceptor material. The article is configured as a photovoltaic cell.

In another aspect, this invention features an article that includes a first electrode containing a plurality of electrically conductive lines, a second electrode, and a photoactive layer between the first and second electrodes. The photoactive layer includes an electron donor material and an electron acceptor material. The electrically conductive lines have a first width at a first portion and a second width at a second portion, in which the second width is different from the first width. The article is configured as a photovoltaic cell.

In another aspect, this invention features a system that includes a first electrode comprising a plurality of electrically conductive lines, a second electrode, and first and second photoactive layers between the first and second electrodes. At least one of the first and second photoactive layers includes an electron donor material and an electron acceptor material. The system is configured as a photovoltaic system.

In another aspect, this invention features a system that includes a first electrode comprising a plurality of electrically conductive lines, a second electrode, and first and second photoactive layers between the first and second electrodes. At least one of the first and second photoactive layers includes an electron donor material and an electron acceptor material. The electrically conductive lines have a first width at a first portion and a second width at a second portion, in which the second width is different from the first width. The system is configured as a photovoltaic system.

Embodiments can include one or more of the following features.

In some embodiments, the second portion is configured to conduct a higher current flow than the first portion and the second width is larger than the first width.

In some embodiments, the difference between the first and second widths is at least about 0.1 μm.

In some embodiments, at least some of the electrically conductive lines are substantially parallel to each other. In certain embodiments, all of the electrically conductive lines are substantially parallel to each other.

In some embodiments, at least some of the electrically conductive lines include trapezoid or triangle shaped lines.

In some embodiments, the electrically conductive lines include a metal, an alloy, a polymer, or a combinations thereof.

In some embodiments, the article further includes a hole carrier layer between the first electrode and the photoactive layer. The hole carrier layer can include a polymer, which can be selected from the group consisting of polythiophenes (e.g., poly(3,4-ethylene dioxythiophene) (PEDOT) or polythienothiophenes), polyanilines, polyvinylcarbazoles, polyphenylenes, polyphenylvinylenes, polysilanes, polythienylenevinylenes, polyisothianaphthanenes, and copolymers thereof. In certain embodiments, the hole carrier layer includes a metal oxide or a carbon nanotube. In some embodiments, the hole carrier layer includes a dopant. Examples of dopants include poly(styrene-sulfonate)s, polymeric sulfonic acids, or fluorinated polymers (e.g., fluorinated ion exchange polymers).

In some embodiments, the first electrode has a surface resistivity, when measured in combination with the hole carrier layer, of at most about 50 Ω/square.

In some embodiments, the electron donor material includes a polymer. The polymer can be selected from the group consisting of polythiophenes, polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof. For example, the electron donor material can include a polymer selected from the group consisting of polythiophenes (e.g., poly(3-hexylthiophene) (P3HT)), polycyclopentadithiophenes (e.g., poly(cyclopentadithiophene-co-benzothiadiazole)), and copolymers thereof.

In some embodiments, the electron acceptor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof. For example, the electron acceptor material can include a substituted fullerene (e.g., C61-phenyl-butyric acid methyl ester (PCBM)).

In some embodiments, the first photoactive layer has a first band gap and the second photoactive layer has a second band gap different from the first band gap.

In some embodiments, the system further includes a recombination layer between the first and second photoactive layers. The recombination layer can include a p-type semiconductor material and an n-type semiconductor material. In certain embodiments, the p-type and n-type semiconductor materials are blended into one layer. In certain embodiments, the recombination layer includes two layers, one layer containing the p-type semiconductor material and the other layer containing the n-type semiconductor material.

In some embodiments, the system includes a tandem photovoltaic cell.

Embodiments can provide one or more of the following advantages.

In some embodiments, the electrically conductive lines have a first width at a first portion and a second width at a second portion, in which the second portion is configured to conduct a higher current flow than the first portion and the second width is larger than the first width. Such a configuration can minimize the power loss resulted from increased current in the electrically conductive lines.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1(a) is a top view of a module containing a plurality of photovoltaic cells;

FIG. 1(b) is a top view of a plurality of photovoltaic cells with trapezoide-shaped electrodes;

FIG. 2 is a cross-sectional view of an embodiment of a photovoltaic cell;

FIG. 3 is a cross-sectional view of an embodiment of a tandem photovoltaic cell.

FIG. 4 is a schematic of a system containing multiple photovoltaic cells electrically connected in series; and

FIG. 5 is a schematic of a system containing multiple photovoltaic cells electrically connected in parallel.

Like reference symbols in the various drawings indicate like elements.

### DETAILED DESCRIPTION

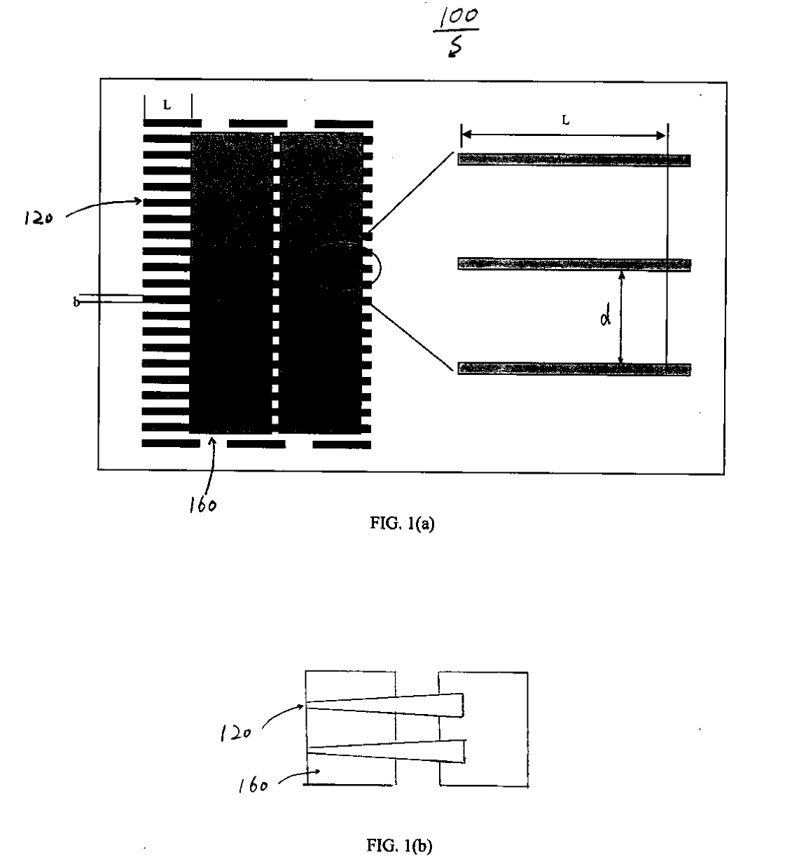

FIG. 1(a) shows a top view of a module 100 containing a plurality of photovoltaic cells. Each cell includes, among others, a bottom electrode 120 and a top electrode 160. As shown in FIG. 1(a), electrodes 120 include a plurality of electrically conductive lines (i.e., grid electrodes) to allow light to pass trough via the space between the lines. Electrode 160 includes an electrically conductive foil and serve as a common electrode for a plurality of photovoltaic cells. Electrode 120 of one photovoltaic cell contacts electrode 160 of another cell at its right end. In some embodiments, electrode 160 can also include a plurality of electrically conductive lines.

In general, electrodes 120 and 160 are formed of an electrically conductive material. Examples of electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum, and alloys of titanium. Exemplary electrically conducting polymers include polythiophenes (e.g., poly(3,4-ethelynedioxythiophene) (PEDOT)), polyanilines (e.g., doped polyanilines), polypyrroles (e.g., doped polypyrroles). Examples of electrically conductive metal oxides include indium tin oxides, fluorinated tin oxides, tin oxides, zinc oxides, and titanium oxides. In some embodiments, combinations of electrically conductive materials are used. In certain embodiments, electrodes 120 are formed entirely of an electrically conductive material (e.g., electrodes 120 are formed of a substantially homogeneous material that is electrically conductive).

The open area between grid electrodes 120 (i.e., between the electrically conductive lines) can vary as desired. Generally, the open area is at least about 10% (e.g., at least about 20%, at least about 30%, at least about 40%, at least about 50%, at least about 60%, at least about 70%, or at least about 80%) and/or at most about 99% (e.g., at most about 95%, at most about 90%, or at most about 85%) of the total area of an electrode layer in module 100. In some embodiments, grid electrodes 120 allow transmittance of at least about 60% (e.g., at least about 70%, at least about 75%, at least about 80%, at least about 85%, at least about 90%, or at least about 95%) of incident light at a wavelength or a range of wavelengths used during operation of the photovoltaic cell.

In some embodiments, electrode 120 or 160 itself is made of a transparent material. As referred to herein, a transparent material is a material which, at the thickness used in a photovoltaic cell 200, transmits at least about 60% (e.g., at least about 70%, at least about 75%, at least about 80%, at least about 85%, at least about 90%, or at least about 95%) of incident light at a wavelength or a range of wavelengths used during operation of the photovoltaic cell.

In some embodiments, electrodes 120 are formed of a first material that is coated with a second material different from the first material (e.g., using metallization or vapor deposition). In general, the first material can be formed of any desired material (e.g., an electrically insulative material or an electrically conductive material), and the second material is an electrically conductive material. Examples of electrically insulative material from which the first material can be formed include textiles, optical fiber materials, polymeric materials (e.g., a nylon) and natural materials (e.g., flax, cotton, wool, silk). Examples of electrically conductive materials from which the first material can be formed include the electrically conductive materials disclosed above. In some embodiments, the first material is in the form of a fiber, and the second material is an electrically conductive material that is coated on the fiber. In certain embodiments, the first material is in the form of a grid (see discussion above) that, after being formed into a grid, is coated with the second material (e.g., PEDOT).

Grid electrodes 120 can have any desired shape (e.g., rectangle, circle, semicircle, triangle, diamond, ellipse, trapezoid, irregular shape) at any cross-section. For example, FIG. 1(a) shows that grid electrode 120 has a rectangular shape from the top view (i.e., the entire electrode 120 having the same width). As another example, FIG. 1(b) shows that grid electrode 120 has a trapezoid shape from the top view, i.e., electrode 120 having a first width at a first portion and a second width at a second portion, in which the second width is different from the first width. In certain embodiments, the difference between the first and second widths is at least about 0.1 μm (e.g., at least about 0.5 μm, at least about 1 μm, at least about 5 μm, at least about 10 μm, at least about 100 μm, at least about 1,000 μm, or at least about 0.01 cm, or at least about 0.1 cm) or at most about 1 cm (e.g., at most about 0.5 cm, at most about 0.1 cm, at most about 0.05 cm, at most about 0.1 cm, or at most about 1,000 μm). In some embodiments, different regions of grid electrode 120 can have different shapes.

While shown in FIG. 1(a) as having a rectangular shape, open regions between grid electrodes 120 can generally have any desired shape (e.g., square, circle, semicircle, triangle, diamond, ellipse, trapezoid, or irregular shape). In some embodiments, different open regions between grid electrodes 120 can have different shapes.

In some embodiments, grid electrode 120 has a surface resistivity, when measured in combination with a hole carrier layer filled in the space between the grid electrode, of at most about 50 Ω/square (e.g., at most about 25 Ω/square, at most about 20 Ω/square, at most about 10 Ω/square, at most about 5 Ω/square, or at most about 1 Ω/square).

Generally, the maximum thickness of grid electrode 120 (i.e., the maximum thickness of grid electrode 120 in a direction substantially perpendicular to the surface of a substrate in contact with grid electrode 120) should be less than the total thickness of the layer above it. Typically, the maximum thickness of grid electrode 120 is at least 0.1 micron (e.g., at least about 0.2 micron, at least about 0.3 micron, at least about 0.4 micron, at least about 0.5 micron, at least about 0.6 micron, at least about 0.7 micron, at least about 0.8 micron, at least about 0.9 micron, at least about one micron) and/or at most about 10 microns (e.g., at most about nine microns, at most about eight microns, at most about seven microns, at most about six microns, at most about five microns, at most about four microns, at most about three microns, at most about two microns).

In some embodiments, electrode 120 or 160 is flexible (e.g., sufficiently flexible to be incorporated in photovoltaic cell 100 using a continuous, roll-to-roll manufacturing process). In certain embodiments, electrode 120 or 160 is semi-rigid or inflexible. In some embodiments, different regions of electrode 120 or 160 can be flexible, semi-rigid or inflexible (e.g., one or more regions flexible and one or more different regions semi-rigid, one or more regions flexible and one or more different regions inflexible).

In general, the layout and shape of grid electrodes 120 in photovoltaic module 100 can vary as desired. In some embodiments, photovoltaic module 100 having grid electrodes 120 can be designed based on (1) power loss resulted from the transport of electrons between electrodes 120, (2) power loss resulted from the transport of electrons in electrodes 120, and (3) absorption loss due to the presence of electrodes 120.

Referring to FIG. 1(a), power loss resulted from the transport of electrons between electrodes 120 (i.e., P) can be calculated by equation (1):
P=I²·R_{sq}·d/6L (1),
in which I refers to the maximum current between two grid electrodes, R_{sq} refers to the surface resistivity of the material (e.g., PEDOT) between two grid electrodes, d refers to the distance between two grid electrodes, and L refers to the length of a grid electrode.

Power loss resulted from the transport of electrons in a grid electrode 120 (i.e., P) can be calculated by equation (2):
P=I²·p·L/(3·α·w) (2),
in which I refers to the maximum current in the grid electrode, p refers to the surface resistivity of the material (e.g., silver) that forms the grid electrode, L refers to the length of the grid electrode, a refers to the thickness of the electrode, and w refers to the width the grid electrode.

Absorption loss due to the presence of electrodes 120 can be obtained based on the percentage of the shading area of the electrode within the entire the electrode layer, which is given by the ratio of the sum of the electrode width and the sum of the distances between the electrodes.

Based on the above three factors, one can design a photovoltaic module having grid electrodes that result in a minimum power/absorption loss. For example, referring to FIG. 1(a), when grid electrodes 120 are made of a known material (e.g., silver, which has a specific resistivity of about 1.6 microΩ·cm), has a fixed width of 100 microns, and is filled with a known material (e.g., PEDOT, which has a surface resistivity of about 100 Ω/square) in the space between grid electrodes, the power/absorption loss of the module varies based on the distance between two grid electrodes and the length of the grid electrode. The relationship between these variables can be expressed in a 3-dimensional graph, from which one can readily determine the optimal distance between two electrodes and the length of the electrode that result in the minimum power/absorption loss.

Equation (2) shows that power loss increases with the increase of current in a grid electrode and with the decrease of the electrode width. In general, the current generated by photovoltaic effects in a photovoltaic module increases inside the photovoltaic module and reaches the highest level at the point where the current exits the module. Thus, to reduce power loss resulted from the increased current, the width of the grid electrode can be increased in the same direction as the current increase. An example of such a configuration is illustrated in FIG. 1(b). In some embodiments, the width (i.e., b in FIG. 1(a)) of grid electrode 120 is at least about 1 μm (e.g., at least about 5 μm, at least about 10 μm, or at least about 50 μm) or at most about 1 cm (e.g., at most about 0.5 cm, at most about 0.1 cm, or at most about 0.05 cm).

In general, the length of grid electrode 120 can be designed based on the three factors described above. It can vary depending on, for example, other dimensions (e.g., width and thickness) of electrodes 120, the distances between two electrode 120, the material used to form electrode 120, and the hole carrier material that fills in the space between electrodes 120. In some embodiments, the length of grid electrode 120 is at least about 0.1 cm (e.g., at least about 0.5 cm, at least about 1 cm, or at least about 5 cm) or at most about 20 cm (e.g., at most about 15 cm, at most about 10 cm, or at most about 5 cm).

The distance between two grid electrodes 120 can generally also be designed based on the three factors described above. It can vary depending on, for example, other dimensions (e.g., width and thickness) of electrodes 120, the material used to form electrode 120, and the hole carrier material that fills in the space between electrodes 120. In some embodiments, the distance between two grid electrodes 120 is at least about 0.01 cm (e.g., at least about 0.05 cm, at least about 0.1 cm, or at least about 0.5 cm) or at most about 10 cm (e.g., at most about 5 cm, at most about 1 cm, or at most about 0.5 cm).

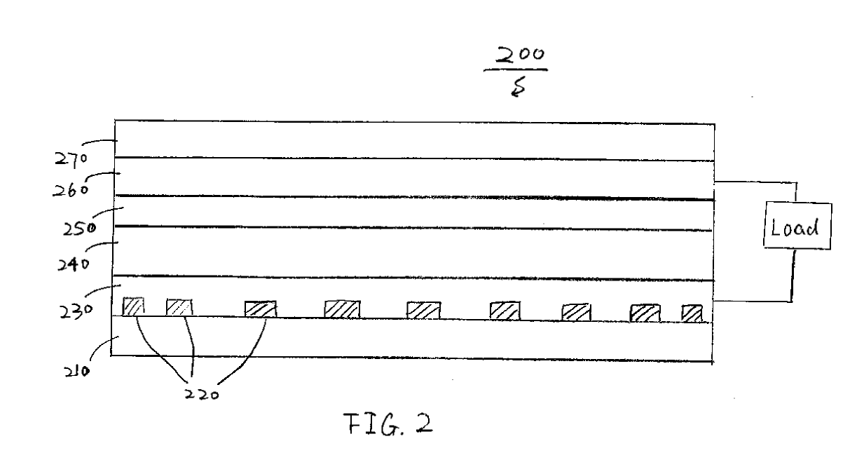

FIG. 2 shows a cross-sectional view of a photovoltaic cell 200 that includes a substrate 210, a cathode 220, a hole carrier layer 230, a photoactive layer 240 (containing an electron acceptor material and an electron donor material), a hole blocking layer 250, an anode 260, and a substrate 270.

In general, during use, light impinges on the surface of substrate 210, and passes through substrate 210, cathode 220, and hole carrier layer 230. The light then interacts with photoactive layer 240, causing electrons to be transferred from the electron donor material in layer 240 to the electron acceptor material in layer 240. The electron acceptor material then transmits the electrons through hole blocking layer 250 to anode 260, and the electron donor material transfers holes through hole carrier layer 230 to cathode 220. Anode 260 and cathode 220 are in electrical connection via an external load so that electrons pass from anode 260, through the load, and to cathode 220.

Substrate 210 is generally formed of a transparent material. Exemplary materials from which substrate 210 can be formed include polyethylene terephthalates, polyimides, polyethylene naphthalates, polymeric hydrocarbons, cellulosic polymers, polycarbonates, polyamides, polyethers and polyether ketones. In certain embodiments, the polymer can be a fluorinated polymer. In some embodiments, combinations of polymeric materials are used. In certain embodiments, different regions of substrate 210 can be formed of different materials.

In general, substrate 210 can be flexible, semi-rigid or rigid (e.g., glass). In some embodiments, substrate 210 has a flexural modulus of less than about 5,000 megaPascals. In certain embodiments, different regions of substrate 210 can be flexible, semi-rigid or inflexible (e.g., one or more regions flexible and one or more different regions semi-rigid, one or more regions flexible and one or more different regions inflexible).

Typically, substrate 210 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 210 can be colored or non-colored. In some embodiments, one or more portions of substrate 210 is/are colored while one or more different portions of substrate 210 is/are non-colored.

Substrate 210 can have one planar surface (e.g., the surface on which light impinges), two planar surfaces (e.g., the surface on which light impinges and the opposite surface), or no planar surfaces. A non-planar surface of substrate 210 can, for example, be curved or stepped. In some embodiments, a non-planar surface of substrate 210 is patterned (e.g., having patterned steps to form a Fresnel lens, a lenticular lens or a lenticular prism).

In general, cathode 220 can have any suitable shape as desired. In some embodiments, cathode 220 can be formed of a plurality of electrically conductive lines (i.e., grid electrodes), such as those described above. In some embodiments, cathode 220 can include a mesh electrode. Examples of mesh electrodes are described in commonly owned co-pending U.S. Patent Application Publication Nos. 20040187911 and 20060090791, the contents of which are hereby incorporated by reference.

Hole carrier layer 230 is generally formed of a material that, at the thickness used in photovoltaic cell 200, transports holes to cathode 220 and substantially blocks the transport of electrons to cathode 220. Examples of materials from which layer 230 can be formed include semiconductive polymers, such as polythiophenes (e.g., PEDOT), polyanilines, polyvinylcarbazoles, polyphenylenes, polyphenylvinylenes, polysilanes, polythienylenevinylenes, polyisothianaphthanenes, and copolymers thereof. In some embodiments, hole carrier layer 230 can include a dopant used in combination with a semiconductive polymer. Examples of dopants include poly(styrene-sulfonate)s, polymeric sulfonic acids, or fluorinated polymers (e.g., fluorinated ion exchange polymers). In some embodiments, the materials that can be used to form hole carrier layer 230 include metal oxides, such as titanium oxides, zinc oxides, tungsten oxides, molybdenum oxides, copper oxides, strontium copper oxides, or strontium titanium oxides. The metal oxides can be either undoped or doped with a dopant. Examples of dopants for metal oxides includes salts or acids of fluoride, chloride, bromide, and iodide. In some embodiments, the materials that can be used to form hole carrier layer 230 include carbon allotropes (e.g., carbon nanotubes). The carbon allotropes can be embedded in a polymer binder. In some embodiments, hole carrier layer 230 can include combinations of hole carrier materials described above. In some embodiments, the hole carrier materials can be in the form of nanoparticles. The nanoparticles can have any suitable shape, such as a spherical, cylindrical, or rod-like shape.

In general, the thickness of hole carrier layer 230 (i.e., the distance between the surface of hole carrier layer 230 in contact with photoactive layer 240 and the surface of cathode 220 in contact with hole carrier layer 230) can be varied as desired. Typically, the thickness of hole carrier layer 230 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some embodiments, the thickness of hole carrier layer 230 is from about 0.01 micron to about 0.5 micron.

Photoactive layer 240 generally contains an electron acceptor material (e.g., an organic electron acceptor material) and an electron donor material (e.g., an organic electron donor material).

Examples of electron acceptor materials include fullerenes, inorganic nanoparticles, oxadiazoles, discotic liquid crystals, carbon nanorods, inorganic nanorods, polymers containing moieties capable of accepting electrons or forming stable anions (e.g., polymers containing CN groups, polymers containing CF₃ groups), or combinations thereof. In some embodiments, the electron acceptor material is a substituted fullerene (e.g., PCBM). In some embodiments, a combination of electron acceptor materials can be used in photoactive layer 240.

Examples of electron donor materials include conjugated polymers, such as polythiophenes, polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxalines, polybenzoisothiazoles, polybenzothiazoles, polythienothiophenes, poly(thienothiophene oxide)s, polyditienothiophenes, poly(dithienothiophene oxide)s, polytetrahydroisoindoles, and copolymers thereof. In some embodiments, the electron donor material can be polythiophenes (e.g., poly(3-hexylthiophene)), polycyclopentadithiophenes, and copolymers thereof. In certain embodiments, a combination of electron donor materials can be used in photoactive layer 240.

In some embodiments, the electron donor materials or the electron acceptor materials can include a polymer having a first comonomer repeat unit and a second comonomer repeat unit different from the first comonomer repeat unit. The first comonomer repeat unit can include a cyclopentadithiophene moiety, a silacyclopentadithiophene moiety, a cyclopentadithiazole moiety, a thiazolothiazole moiety, a thiazole moiety, a benzothiadiazole moiety, a thiophene oxide moiety, a cyclopentadithiophene oxide moiety, a polythiadiazoloquinoxaline moiety, a benzoisothiazole moiety, a benzothiazole moiety, a thienothiophene moiety, a thienothiophene oxide moiety, a dithienothiophene moiety, a dithienothiophene oxide moiety, or a tetrahydroisoindoles moiety.

In some embodiments, the first comonomer repeat unit includes a cyclopentadithiophene moiety. In some embodiments, the cyclopentadithiophene moiety is substituted with at least one substituent selected from the group consisting of C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, and SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, the cyclopentadithiophene moiety can be substituted with hexyl, 2-ethylhexyl, or 3,7-dimethyloctyl. In certain embodiments, the cyclopentadithiophene moiety is substituted at 4-position. In some embodiments, the first comonomer repeat unit can include a cyclopentadithiophene moiety of formula (1): 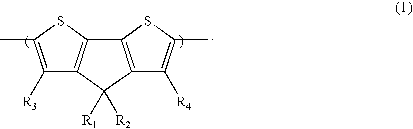
In formula (1), each of H, C₁-C₂₀ alkyl, C₁-C₂₀ alkoxy, C₃-C₂₀ cycloalkyl, C₁-C₂₀ heterocycloalkyl, aryl, heteroaryl, halo, ON, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, each of R₁ and R₂, independently, can be hexyl, 2-ethylhexyl, or 3,7-dimethyloctyl.

An alkyl can be saturated or unsaturated and branch or straight chained. A C₁-C₂₀ alkyl contains 1 to 20 carbon atoms (e.g., one, two, three, four, five, six, seven, eight, nine, 10, 11, 12, 13, 14, 15, 16, 17, 18, 19, and 20 carbon atoms). Examples of alkyl moieties include —CH₃, —CH₂—, —CH₂═CH₂—, —CH₂—CH═CH₂, and branched —C₃H₇. An alkoxy can be branch or straight chained and saturated or unsaturated. An C₁-C₂₀ alkoxy contains an oxygen radical and 1 to 20 carbon atoms (e.g., one, two, three, four, five, six, seven, eight, nine, 10, 11, 12, 13, 14, 15, 16, 17, 18, 19, and 20 carbon atoms). Examples of alkoxy moieties include —OCH₃ and —OCH═CH—CH₃. A cycloalkyl can be either saturated or unsaturated. A C₃-C₂₀ cycloalkyl contains 3 to 20 carbon atoms (e.g., three, four, five, six, seven, eight, nine, 10, 11, 12, 13, 14, 15, 16, 17, 18, 19, and 20 carbon atoms). Examples of cycloalkyl moieties include cyclohexyl and cyclohexen-3-yl. A heterocycloalkyl can also be either saturated or unsaturated. A C₃-C₂₀ heterocycloalkyl contains at least one ring heteroatom (e.g., O, N, and S) and 3 to 20 carbon atoms (e.g., three, four, five, six, seven, eight, nine, 10, 11, 12, 13, 14, 15, 16, 17, 18, 19, and 20 carbon atoms). Examples of heterocycloalkyl moieties include 4-tetrahydropyranyl and 4-pyranyl. An aryl can contain one or more aromatic rings. Examples of aryl moieties include phenyl, phenylene, naphthyl, naphthylene, pyrenyl, anthryl, and phenanthryl. A heteroaryl can contain one or more aromatic rings, at least one of which contains at least one ring heteroatom (e.g., O, N, and S). Examples of heteroaryl moieties include furyl, furylene, fluorenyl, pyrrolyl, thienyl, oxazolyl, imidazolyl, thiazolyl, pyridyl, pyrimidinyl, quinazolinyl, quinolyl, isoquinolyl, and indolyl.

Alkyl, alkoxy, cycloalkyl, heterocycloalkyl, aryl, and heteroaryl mentioned herein include both substituted and unsubstituted moieties, unless specified otherwise. Examples of substituents on cycloalkyl, heterocycloalkyl, aryl, and heteroaryl include C₁-C₂₀ alkyl, C₃-C₂₀ cycloalkyl, C₁-C₂₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, C₁-C₁₀ arylthio, arylthio, C₁-C₁₀ alkylsulfonyl, arylsulfonyl, cyano, nitro, acyl, acyloxy, carboxyl, and carboxylic ester. Examples of substituents on alkyl include all of the above-recited substituents except C₁-C₂₀ alkyl. Cycloalkyl, heterocycloalkyl, aryl, and heteroaryl also include fused groups.

The second comonomer repeat unit can include a benzothiadiazole moiety, a thiadiazoloquinoxaline moiety, a cyclopentadithiophene oxide moiety, a benzoisothiazole moiety, a benzothiazole moiety, a thiophene oxide moiety, a thienothiophene moiety, a thienothiophene oxide moiety, a dithienothiophene moiety, a dithienothiophene oxide moiety, a tetrahydroisoindole moiety, a fluorene moiety, a silole moiety, a cyclopentadithiophene moiety, a fluorenone moiety, a thiazole moiety, a selenophene moiety, a thiazolothiazole moiety, a cyclopentadithiazole moiety, a naphthothiadiazole moiety, a thienopyrazine moiety, a silacyclopentadithiophene moiety, an oxazole moiety, an imidazole moiety, a pyrimidine moiety, a benzoxazole moiety, or a benzimidazole moiety. In some embodiments, the second comonomer repeat unit is a 3,4-benzo-1,2,5-thiadiazole moiety.

In some embodiments, the second comonomer repeat unit can include a benzothiadiazole moiety of formula (2), a thiadiazoloquinoxaline moiety of formula (3), a cyclopentadithiophene dioxide moiety of formula (4), a cyclopentadithiophene monoxide moiety of formula (5), a benzoisothiazole moiety of formula (6), a benzothiazole moiety of formula (7), a thiophene dioxide moiety of formula (8), a cyclopentadithiophene dioxide moiety of formula (9), a cyclopentadithiophene tetraoxide moiety of formula (10), a thienothiophene moiety of formula (11), a thienothiophene tetraoxide moiety of formula (12), a dithienothiophene moiety of formula (13), a dithienothiophene dioxide moiety of formula (14), a dithienothiophene tetraoxide moiety of formula (15), a tetrahydroisoindole moiety of formula (16), a thienothiophene dioxide moiety of formula (17), a dithienothiophene dioxide moiety of formula (18), a fluorene moiety of formula (19), a silole moiety of formula (20), a cyclopentadithiophene moiety of formula (21), a fluorenone moiety of formula (22), a thiazole moiety of formula (23), a selenophene moiety of formula (24), a thiazolothiazole moiety of formula (25), a cyclopentadithiazole moiety of formula (26), a naphthothiadiazole moiety of formula (27), a thienopyrazine moiety of formula (28), a silacyclopentadithiophene moiety of formula (29), an oxazole moiety of formula (30), an imidazole moiety of formula (31), a pyrimidine moiety of formula (32), a benzoxazole moiety of formula (33), or a benzimidazole moiety of formula (34): 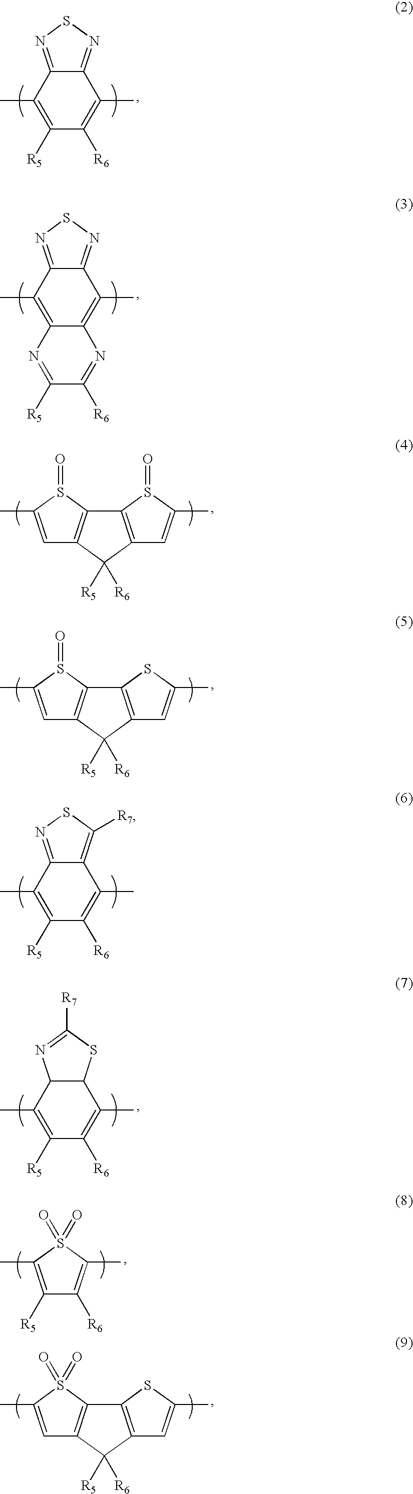 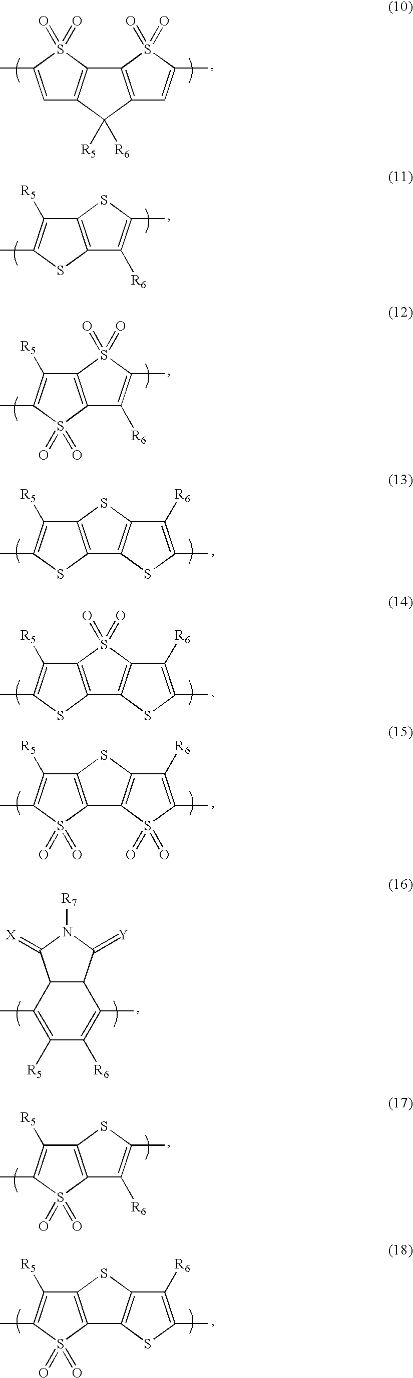 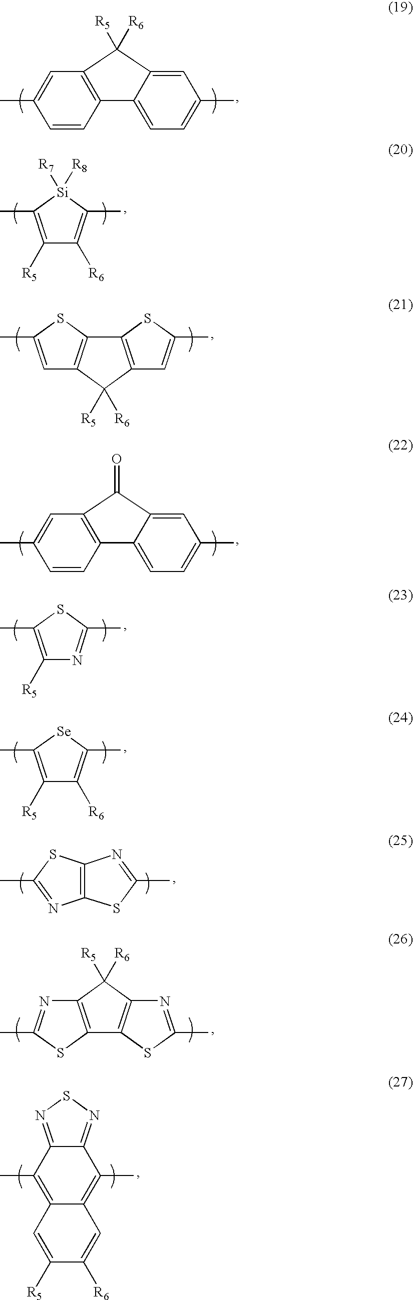 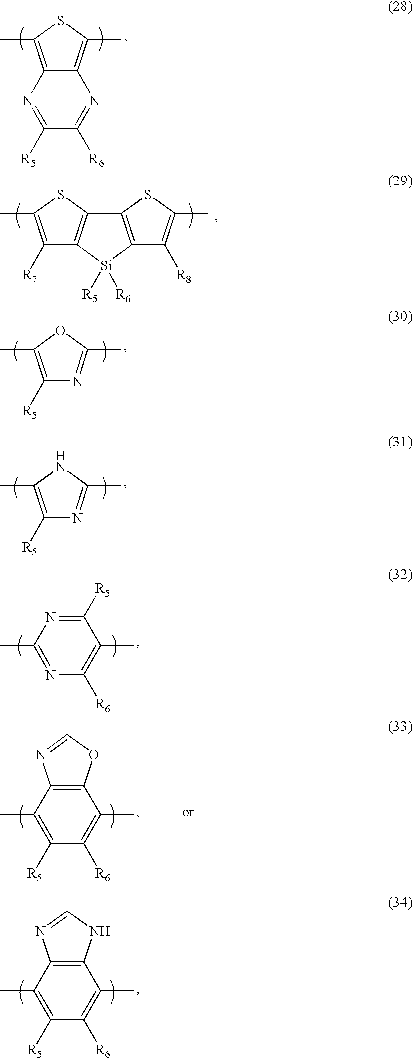
In the above formulas, each of X and Y, independently, is CH₂, O, or S; each of R₅ and R₆, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R, in which R is H, C₁-C₂₀ alkyl, C₁-C₂₀ alkoxy, aryl, heteroaryl, C₃-C₂₀ cycloalkyl, or C₁-C₂₀ heterocycloalkyl; and each of R₇ and R₈, independently, is H, C₁-C₂₀ alkyl, C₁-C₂₀ alkoxy, aryl, heteroaryl, C₃-C₂₀ cycloalkyl, or C₃-C₂₀ heterocycloalkyl. In some embodiments, the second comonomer repeat unit includes a benzothiadiazole moiety of formula (2), in which each of R₅ and R₆ is H.

The second comonomer repeat unit can include at least three thiophene moieties. In some embodiments, at least one of the thiophene moieties is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl. In certain embodiments, the second comonomer repeat unit includes five thiophene moieties.

The polymer can further include a third comonomer repeat unit that contains a thiophene moiety or a fluorene moiety. In some embodiments, the thiophene or fluorene moiety is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl.

In some embodiments, the polymer can be formed by any combination of the first, second, and third comonomer repeat units. In certain embodiments, the polymer can be a homopolymer containing any of the fist, second, and third comonomer repeat units.

In some embodiments, the polymer can be 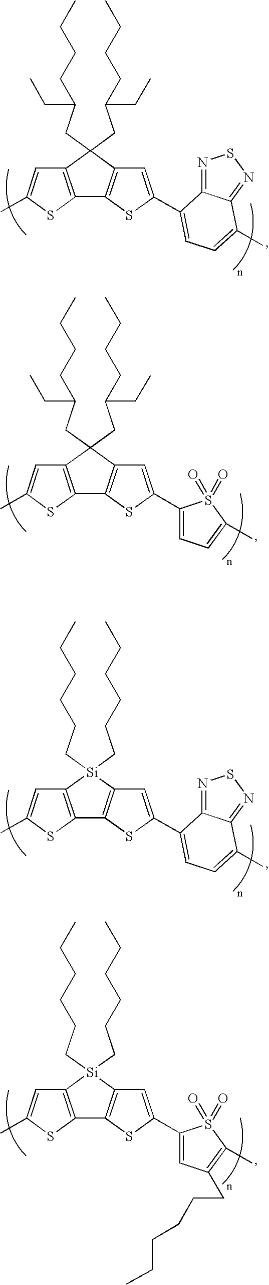 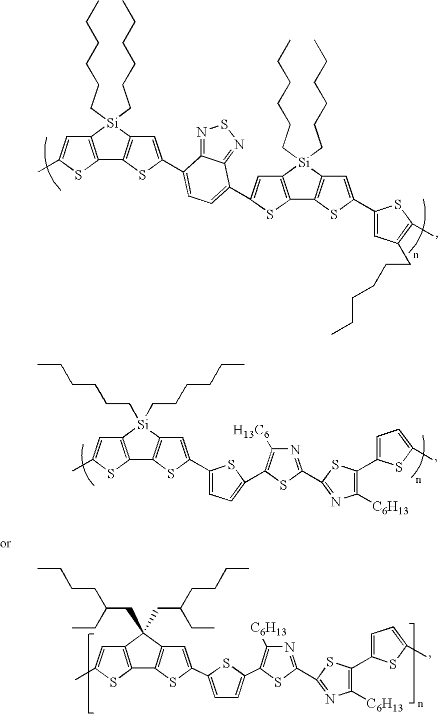
in which n can be an integer greater than 1.

The monomers for preparing the polymers mentioned herein may contain a non-aromatic double bond and one or more asymmetric centers. Thus, they can occur as racemates and racemic mixtures, single enantiomers, individual diastereomers, diastereomeric mixtures, and cis- or trans-isomeric forms. All such isomeric forms are contemplated.

The polymers described above can be prepared by methods known in the art, such as those described in commonly owned co-pending U.S. application Ser. No. 11/601,374, the contents of which are hereby incorporated by reference. For example, a copolymer can be prepared by a cross-coupling reaction between one or more comonomers containing two alkylstannyl groups and one or more comonomers containing two halo groups in the presence of a transition metal catalyst. As another example, a copolymer can be prepared by a cross-coupling reaction between one or more comonomers containing two borate groups and one or more comonomers containing two halo groups in the presence of a transition metal catalyst. The comonomers can be prepared by the methods known in the art such as those described in U.S. patent application Ser. No. 11/486,536, Coppo et al., Macromolecules 2003, 36, 2705-2711 and Kurt et al., J. Heterocycl. Chem. 1970, 6, 629, the contents of which are hereby incorporated by reference.

Without wishing to be bound by theory, it is believed that an advantage of the polymers described above is that their absorption wavelengths shift toward the red and near IR regions (e.g., 650-800 nm) of the electromagnetic spectrum, which is not accessible by most other conventional polymers. When such a polymer is incorporated into a photovoltaic cell together with a conventional polymer, it enables the cell to absorb the light in this region of the spectrum, hereby increasing the current and efficiency of the cell.

Generally, photoactive layer 240 is sufficiently thick to be relatively efficient at absorbing photons impinging thereon to form corresponding electrons and holes, and sufficiently thin to be relatively efficient at transporting the holes and electrons. In certain embodiments, photoactive layer 240 is at least 0.05 micron (e.g., at least about 0.1 micron, at least about 0.2 micron, or at least about 0.3 micron) thick and/or at most about one micron (e.g., at most about 0.5 micron or at most about 0.4 micron) thick. In some embodiments, photoactive layer 240 is from about 0.1 micron to about 0.2 micron thick.

Hole blocking layer 250 is generally formed of a material that, at the thickness used in photovoltaic cell 200, transports electrons to anode 260 and substantially blocks the transport of holes to anode 260. Examples of materials from which layer 250 can be formed include LiF, amines (e.g., primary, secondary, or tertiary amines), and metal oxides (e.g., zinc oxide or titanium oxide).

Typically, hole blocking layer 250 is at least 0.02 micron (e.g., at least about 0.03 micron, at least about 0.04 micron, or at least about 0.05 micron) thick and/or at most about 0.5 micron (e.g., at most about 0.4 micron, at most about 0.3 micron, at most about 0.2 micron, or at most about 0.1 micron) thick.

Anode 260 is generally formed of an electrically conductive material, such as one or more of the electrically conductive materials described above. In some embodiments, anode 260 is formed of a combination of electrically conductive materials. In certain embodiments, anode 260 can be formed of a mesh electrode.

Substrate 270 can be identical to or different from substrate 210. In some embodiments, substrate 270 can be formed of one or more suitable polymers, such as those described above.

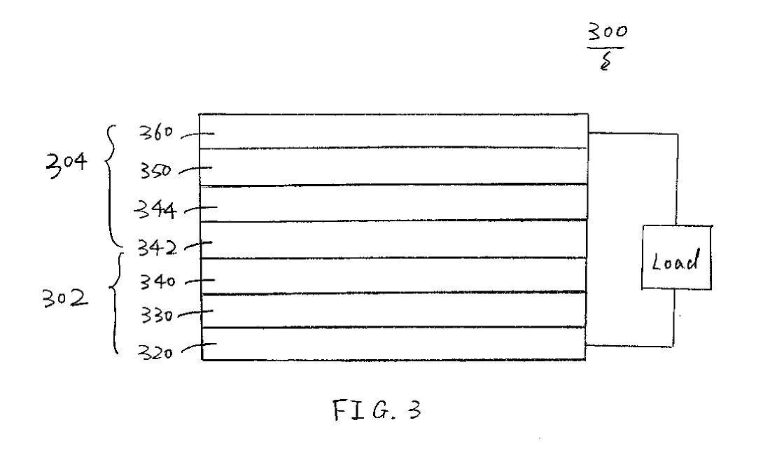

FIG. 3 shows a tandem photovoltaic cell 300 having two semi-cells 302 and 304. Semi-cell 302 includes a cathode 320, a hole carrier layer 330, a first photoactive layer 340, and a recombination layer 342. Semi-cell 304 includes recombination layer 342, a second photoactive layer 344, a hole blocking layer 350, and an anode 360. An external load is connected to photovoltaic cell 300 via cathode 320 and anode 360. Depending on the production process and the desired device architecture, the current flow in a semi-cell can be reversed by changing the electron/hole conductivity of a certain layer (e.g., changing hole blocking layer 350 to a hole carrier layer). By doing so, a tandem cell can be designed such that the semi-cells in the tandem cells can be electrically interconnected either in series or in parallel.

A recombination layer refers to a layer in a tandem cell where the electrons generated from a first semi-cell recombine with the holes generated from a second semi-cell. Recombination layer 342 typically includes a p-type semiconductor material and an n-type semiconductor material. In general, n-type semiconductor materials selectively transport electrons and p-type semiconductor materials selectively transport holes. As a result, electrons generated from the first semi-cell recombine with holes generated from the second semi-cell at the interface of the n-type and p-type semiconductor materials.

In some embodiments, the p-type semiconductor material includes a polymer and/or a metal oxide. Examples p-type semiconductor polymers include polythiophenes (e.g., poly(3,4-ethylene dioxythiophene) (PEDOT)), polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof. The metal oxide can be an intrinsic p-type semiconductor (e.g., copper oxides, strontium copper oxides, or strontium titanium oxides) or a metal oxide that forms a p-type semiconductor after doping with a dopant (e.g., p-doped zinc oxides or p-doped titanium oxides). Examples of dopants includes salts or acids of fluoride, chloride, bromide, and iodide. In some embodiments, the metal oxide can be used in the form of nanoparticles.

In some embodiments, the n-type semiconductor material includes a metal oxide, such as titanium oxides, zinc oxides, tungsten oxides, molybdenum oxides, and combinations thereof. The metal oxide can be used in the form of nanoparticles. In other embodiments, the n-type semiconductor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

In some embodiments, the p-type and n-type semiconductor materials are blended into one layer. In certain embodiments, the recombination layer includes two layers, one layer including the p-type semiconductor material and the other layer including the n-type semiconductor material.

In some embodiments, recombination layer 342 includes at least about 30 wt % (e.g., at least about 40 wt % or at least about 50 wt %) and/or at most about 70 wt % (e.g., at most about 60 wt % or at most about 50 wt %) of the p-type semiconductor material. In some embodiments, recombination layer 342 includes at least about 30 wt % (e.g., at least about 40 wt % or at least about 50 wt %) and/or at most about 70 wt % (e.g., at most about 60 wt % or at most about 50 wt %) of the n-type semiconductor material.

Recombination layer 342 generally has a sufficient thickness so that the layers underneath are protected from any solvent applied onto recombination layer 342. In some embodiments, recombination layer 342 can have a thickness at least about 10 nm (e.g., at least about 20 nm, at least about 50 nm, or at least about 100 nm) and/or at most about 500 nm (e.g., at most about 200 nm, at most about 150 nm, or at most about 100 nm).

In general, recombination layer 342 is substantially transparent. For example, at the thickness used in a tandem photovoltaic cell 300, recombination layer 342 can transmit at least about 70% (e.g., at least about 75%, at least about 80%, at least about 85%, or at least about 90%) of incident light at a wavelength or a range of wavelengths (e.g., from about 350 nm to about 1,000 nm) used during operation of the photovoltaic cell.

Recombination layer 342 generally has a sufficiently low resistivity. In some embodiments, recombination layer 342 has a resistivity of at most about 1×10⁶ ohm/square, (e.g., at most about 5×10⁵ ohm/square, at most about 2×10⁵ ohm/square, or at most about 1×10⁵ ohm/square).

Without wishing to be bound by theory, it is believed that recombination layer 342 can be considered as a common electrode between two semi-cells (e.g., one including cathode 320, hole carrier layer 330, photoactive layer 340, and recombination layer 342, and the other include recombination layer 342, photoactive layer 344, hole blocking layer 350, and anode 360) in photovoltaic cells 300. In some embodiments, recombination layer 342 can include an electrically conductive mesh material, such as those described above. An electrically conductive mesh material can provide a selective contact of the same polarity (either p-type or n-type) to the semi-cells and provide a highly conductive but transparent layer to transport electrons to a load.

In some embodiments, recombination layer 342 can be prepared by applying a blend of an n-type semiconductor material and a p-type semiconductor material on photoactive layer. For example, an n-type semiconductor and a p-type semiconductor can be first dispersed and/or dissolved in a solvent together to form a dispersion or solution and then coated the dispersion or solution on a photoactive layer to form a recombination layer.

In some embodiments, recombination layer 342 can include two or more layers with required electronic and optical properties for tandem cell functionality. For example, recombination layer 342 includes a layer that contains an n-type semiconductor material and a layer that contains a p-type semiconductor material. In such embodiments, recombination layer 342 can include a layer of mixed n-type and p-type semiconductor material at the interface of the two layers.

In some embodiments, a two-layer recombination layer can be prepared by applying a layer of an n-type semiconductor material and a layer of a p-type semiconductor material separately. For example, when titanium oxide nanoparticles are used as an n-type semiconductor material, a layer of titanium oxide nanoparticles can be formed by (1) dispersing a precursor (e.g., a titanium salt) in a solvent (e.g., an anhydrous alcohol) to form a dispersion, (2) coating the dispersion on a photoactive layer, (3) hydrolyzing the dispersion to form a titanium oxide layer, and (4) drying the titanium oxide layer. As another example, when a polymer (e.g., PEDOT) is used a p-type semiconductor, a polymer layer can be formed by first dissolving the polymer in a solvent (e.g., an anhydrous alcohol) to form a solution and then coating the solution on a photoactive layer.

Other components in tandem cell 300 can be identical to those in photovoltaic cell 200 described above.

In some embodiments, the semi-cells in a tandem cell are electrically interconnected in series. When connected in series, in general, the layers can be in the order shown in FIG. 3. In certain embodiments, the semi-cells in a tandem cell are electrically interconnected in parallel. When interconnected in parallel, a tandem cell having two semi-cells can include the following layers: a first cathode, a first hole carrier layer, a first photoactive layer, a first hole blocking layer (which can serve as an anode), a second hole blocking layer (which can serve as an anode), a second photoactive layer, a second hole carrier layer, and a second cathode. In such embodiments, the first and second hole blocking layers can be either two separate layers or can be one single layer. In case the conductivity of the first and second hole blocking layer is not sufficient, an additional layer (e.g., an electrically conductive mesh layer) providing the required conductivity may be inserted.

In some embodiments, a tandem cell can include more than two semi-cells (e.g., three, four, five, six, seven, eight, nine, ten, or more semi-cells). In certain embodiments, some semi-cells can be electrically interconnected in series and some semi-cells can be electrically interconnected in parallel.

In general, the methods of preparing each layer in photovoltaic cells described in FIGS. 2 and 3 can vary as desire. In some embodiments, a layer can be prepared by a liquid-based coating process. The term “liquid-based coating process” mentioned herein refers to a process that uses a liquid-based coating composition. Examples of the liquid-based coating composition can be a solution, a dispersion, or a suspension. The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Examples of liquid-based coating processes have been described in, for example, commonly-owned co-pending U.S. Application 60/888,704, the contents of which are hereby incorporated by reference. In certain embodiments, a layer can be prepared via a gas phase-based coating process, such as chemical or physical vapor deposition processes.

In some embodiments, the photovoltaic cells described in FIGS. 2 and 3 can be prepared in a continuous manufacturing process, such as a roll-to-roll process, thereby significantly reducing the preparation cost. Examples of roll-to-roll processes have been described in, for example, commonly-owned co-pending U.S. Application Publication No. 2005-0263179, the contents of which are hereby incorporated by reference.

While certain embodiments have been disclosed, other embodiments are also possible.

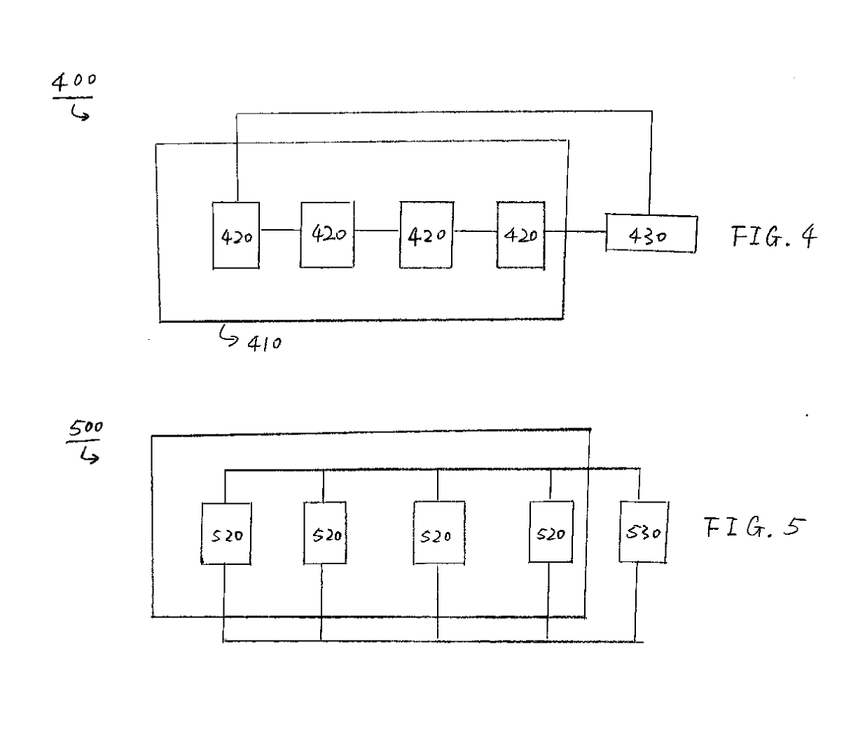

In some embodiments, multiple photovoltaic cells can be electrically connected to form a photovoltaic system. As an example, FIG. 4 is a schematic of a photovoltaic system 400 having a module 410 containing photovoltaic cells 420. Cells 420 are electrically connected in series, and system 400 is electrically connected to a load 430. As another example, FIG. 5 is a schematic of a photovoltaic system 500 having a module 510 that contains photovoltaic cells 520. Cells 520 are electrically connected in parallel, and system 500 is electrically connected to a load 530. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

Other embodiments are in the claims.

What is claimed is:

1. An article, comprising:
a first electrode comprising a plurality of electrically conductive lines;
a second electrode; and
a photoactive layer between the first and second electrodes, the photoactive layer comprising an electron donor material and an electron acceptor material;
wherein the electrically conductive lines have a first width at a first portion and a second width at a second portion, the second width is different from the first width, and the article is configured as a photovoltaic cell.

2. The article of claim 1, wherein the second portion is configured to conduct a higher current flow than the first portion and the second width is larger than the first width.

3. The article of claim 1, wherein the difference between the first and second widths is at least about 0.1 μm.

4. The article of claim 1, wherein at least some of the electrically conductive lines are substantially parallel to each other.

5. The article of claim 1, wherein all of the electrically conductive lines are substantially parallel to each other.

6. The article of claim 1, wherein at least some of the electrically conductive lines comprise trapezoid or triangle shaped lines.

7. The article of claim 1, wherein the electrically conductive lines comprise a metal, an alloy, a polymer, or a combinations thereof.

8. The article of claim 7, wherein the electrically conductive lines comprise a metal.

9. The article of claim 1, further comprising a hole carrier layer between the first electrode and the photoactive layer.

10. The article of claim 9, wherein the hole carrier layer comprises a polymer.

11. The article of claim 10, wherein the polymer is selected from the group consisting of polythiophenes, polyanilines, polyvinylcarbazoles, polyphenylenes, polyphenylvinylenes, polysilanes, polythienylenevinylenes, polyisothianaphthanenes, and copolymers thereof.

12. The article of claim 11, wherein the polymer comprises poly(3,4-ethylene dioxythiophene).

13. The article of claim 9, wherein the hole carrier layer comprises a metal oxide or a carbon nanotube.

14. The article of claim 9, wherein the hole carrier layer comprises a dopant.

15. The article of claim 14, wherein the dopant comprises poly(styrene-sulfonate).

16. The article of claim 9, wherein the first electrode has a surface resistivity, when measured in combination with the hole carrier layer, of at most about 50 Ω/square.

17. The article of claim 1, wherein the electron donor material comprises a polymer.

18. The article of claim 17, wherein the polymer is selected from the group consisting of polythiophenes, polyanilines, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polytetrahydroisoindoles, and copolymers thereof.

19. The article of claim 18, wherein the electron donor material comprises a polymer selected from the group consisting of polythiophenes, polycyclopentadithiophenes, and copolymers thereof.

20. The article of claim 19, wherein the electron donor material comprises poly(3-hexylthiophene) or poly(cyclopentadithiophene-co-benzothiadiazole).

21. The article of claim 1, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

22. The article of claim 21, wherein the electron acceptor material comprises a substituted fullerene.

23. The article of claim 22, wherein the substituted fullerene comprises PCBM.

24. A system, comprising:
a first electrode comprising a plurality of electrically conductive lines;
a second electrode; and
first and second photoactive layers between the first and second electrodes, at least one of the first and second photoactive layers comprising an electron donor material and an electron acceptor material;
wherein the electrically conductive lines have a first width at a first portion and a second width at a second portion, the second width is different from the first width, and the system is configured as a photovoltaic system.

25. The system of claim 24, wherein the second portion is configured to conduct a higher current flow than the first portion and the second width is larger than the first width.

26. The system of claim 24, wherein the difference between the first and second widths is at least about 0.1 μm.

27. The system of claim 24, wherein at least some of the electrically conductive lines are substantially parallel to each other.

28. The system of claim 24, wherein all of the electrically conductive lines are substantially parallel to each other.

29. The system of claim 24, wherein at least some of the electrically conductive lines comprise trapezoid or triangle shaped lines.

30. The system of claim 24, wherein the electrically conductive lines comprise a metal, an alloy, a polymer, or a combinations thereof.

31. The system of claim 24, wherein the electrically conductive lines comprise a metal.

32. The system of claim 24, further comprising a hole carrier layer between the first electrode and the first photoactive layer.

33. The system of claim 24, wherein the first photoactive layer has a first band gap and the second photoactive layer has a second band gap different from the first band gap.

34. The system of claim 24, further comprising a recombination layer between the first and second photoactive layers.

35. The system of claim 34, wherein the recombination layer comprises a p-type semiconductor material and an n-type semiconductor material.

36. The system of claim 35, wherein the p-type and n-type semiconductor materials are blended into one layer.

37. The system of claim 35, wherein the recombination layer comprises two layers, one layer comprising the p-type semiconductor material and the other layer comprising the n-type semiconductor material.

38. The system of claim 24, wherein the system comprises a tandem photovoltaic cell.
